(19) United States
(12) Patent Application Publication
(10) Pub. No.: US 2014/0214346 A1
(43) Pub. Date: Jul. 31, 2014

(54) ADAPTIVE AVAILABLE POWER ESTIMATION FOR HIGH VOLTAGE LITHIUM ION BATTERY

(71) Applicant: CUMMINS INC., Columbus, IN (US)

(72) Inventors: Lining ZHOU, Columbus, IN (US); Martin T. BOOKS, Columbus, IN (US)

(73) Assignee: CUMMINS INC., Columbus, IN (US)

(21) Appl. No.: 13/750,860

(22) Filed: Jan. 25, 2013

(51) Int. Cl. G01R 31/36

(52) U.S. Cl. CPC G01R 31/362
USPC 702/63; 324/433

(57) ABSTRACT

The present invention provides for a method and computer program product for estimating battery available power from a battery system in relation to a cell voltage, comprising: determining the cell voltage, a power command of the battery system; and a cell voltage threshold. The processes used by the present invention, include a static and a dynamic portion in which cell voltages, cell voltage thresholds and power command are associated and processed using a feed forward estimator and a proportional-integral-derivation (PID) controller to determine the final power command estimation for the requisite battery system.

### FIELD OF INVENTION

The present invention is generally directed to the field of batteries and more particularly to estimation techniques of available power of a battery in relation to external power commands.

### BACKGROUND OF THE INVENTION

A battery's life is dependent upon the proper charging and discharging of cells within a battery, in relation to the loads and demands that are placed on a battery in operation. For instance, a High Voltage (HV) Lithium-Ion (Li-Ion) battery is comprised of cells which can be charged and discharged to an extent where the Li-Ion battery is viewed as a better performer in retaining charge and not discharging as substantially as other battery types.

In operation, a Li-Ion battery's performance is directly related to its cell voltage, which is also one of the principally changing characteristics of the battery. The dynamics of battery cell voltage is directly influenced by battery current as is generally familiar under Ohms law with certain degree of uncertainty in the cell impedance model. The cell voltage of a battery typically has a working boundary during the battery operations, which the battery is anticipated to operate within. However, as the load on the battery may change instantaneously, the voltage may change dynamically with the instantaneous current charge or discharge. As a result, the working boundaries of the voltage of the battery may be exceeded in relation to the load.

In a hybrid engine operation that involves a battery arranged with an engine where the engine may act to charge the battery and one or both of the battery and engine may act to power a connected drivetrain or chassis, ensuring that the battery is accurately charged or discharged while it is operative within its desired working boundaries is important. For, in the above example, where the battery has estimated an amount of available power and the load on the battery creates a demand that causes the battery to exceed it working boundaries (in other words, available power, for example), the hybrid solution will not efficiently benefit from the battery's operation.

In operation today, as a battery's operation is often related to its state of charge (SOC) and the temperature at which it is operating, look-up tables provide information about a battery and its available power in relation to the SOC and the cell temperature. While this approach provides information of available power of the battery that may be of interest in certain situations, the information determined does not account for transient periods and does not provide information that benefits the performance of a hybrid system.

For instance, both the SOC and the cell temperature of a battery are lagging indicators of a present state of the battery, where even using the look-up tables, the resulting information is generally historical and not instantaneous. Similarly, during transient periods, where there may be a sudden demand or surge for power, the look-up table in effect acts to limit power as a fast transient variable, such that the look-up table calculations are lagging in actual transient power demand changes and needs. In the latter situation, where the look-up table is unable to maintain or “catch up” with the transient changes to power, the cell voltage of the battery will exceed its working boundary resulting in an open battery contactor and cessation electrical operation of a hybrid system, for instance. Similarly, for a battery system (e.g., hybrid engine, batteries, system having power from at least a single battery in part, etc.) where the determination of the power available from the system is inaccurate, when the power limit is reached by a load applied to the battery system, there is a risk of the system limit being exceeded or an overvoltage occurring which may be mission disabling.

What is needed is an approach which may adaptively determine available power as an operating limit of the battery in relation to a cell voltage reading, where the available power can be adjusted and the cell voltage may be regulated over a predetermined working boundary range for minimal over-shoot.

### SUMMARY OF THE INVENTION

The present invention provides for a method for estimating available power from a battery system in relation to a cell voltage, comprising: determining the cell voltage, power command of the battery system; and a cell voltage threshold. The method also includes calculating a power adjustment in relation to the cell voltage and the cell voltage threshold and generating a final power command in relation to the power command and the calculated power adjustment. In one or more preferred embodiments, the step of calculating the power adjustment includes, using a regulator to determine a power limit feedback.

The present invention further provides for a system for estimating battery available power from a battery system in relation to a cell voltage, in combination with an engine having a battery power source. The system includes the engine including a communication with the battery power source to receive power therefrom and to provide power thereto for charging and discharging; at least one sensor capable of determining cell voltage of the battery source at a specific time; and, at least one data sensor operatively coupled to detect at least one or more data inputs of engine characteristics of the engine.

Preferably the system further includes a control system for the engine and the battery source; and, a data processor connected with the at least one data sensor for determining the cell voltage and a system power command of the battery source; determining a cell voltage threshold; calculating a power adjustment in relation to the cell voltage and the cell voltage threshold; and generating a final power command for the battery source.

A further embodiment of the present invention includes a computer program product stored on a computer usable medium for estimating battery available power from a battery system in relation to a cell voltage. The program product includes a computer readable program for causing a computer to control an execution of an application within a memory control device in operable communications with an engine. Preferably the computer readable program when executed by a computer for: determining the cell voltage and a power command; determining a cell voltage threshold; and calculating a power adjustment in relation to the cell voltage and the cell voltage threshold for adaptively regulating the cell voltage. The program product also generates a final available power in relation to the estimated battery available power, the power command and the calculated power adjustment.

Further embodiments, forms, objects, features, advantages, aspects, and benefits of the present application shall become apparent from the detailed description and drawings included herein.

### BRIEF DESCRIPTION OF THE DRAWINGS

FIG. 1 is an illustration of a block diagram of one form of the control system of the present invention in accordance with an embodiment of the present invention;

FIG. 2 is a block diagram of a method of the present invention in accordance with one or more embodiments thereof;

FIG. 3 sets forth a block diagram hierarchy of the active or inactive operation of the integrator and anti-windup processing of the present invention in accordance with one or more preferred embodiments; and,

FIG. 4 sets forth a flowchart of the present invention in accordance with one embodiment.

### DETAILED DESCRIPTION OF THE ILLUSTRATIVE EMBODIMENTS

The following description is presented to enable one of ordinary skill in the art to make and use the invention and is provided in the context of a patent application and its requirements. Various modifications to the preferred embodiments and the generic principles and features described herein will be readily apparent to those skilled in the art. Thus, the present invention is not intended to be limited to the embodiments shown, but is to be accorded the widest scope consistent with the principles and features described herein.

For the purposes of promoting an understanding of the principles of the invention, reference will now be made to the embodiments illustrated in the drawings and specific language will be used to describe the same. It will nevertheless be understood that no limitation of the scope of the invention is thereby intended, such alterations, modifications, and further applications of the principles of the present invention as illustrated herein being contemplated as would normally occur to one skilled in the art to which the invention relates.

The present invention provides for a method, control system, computer program product providing a method for estimating battery available power from a battery system in relation to a cell voltage, over known approaches, and is applicable for many applications including internal combustion and hybrid engines.

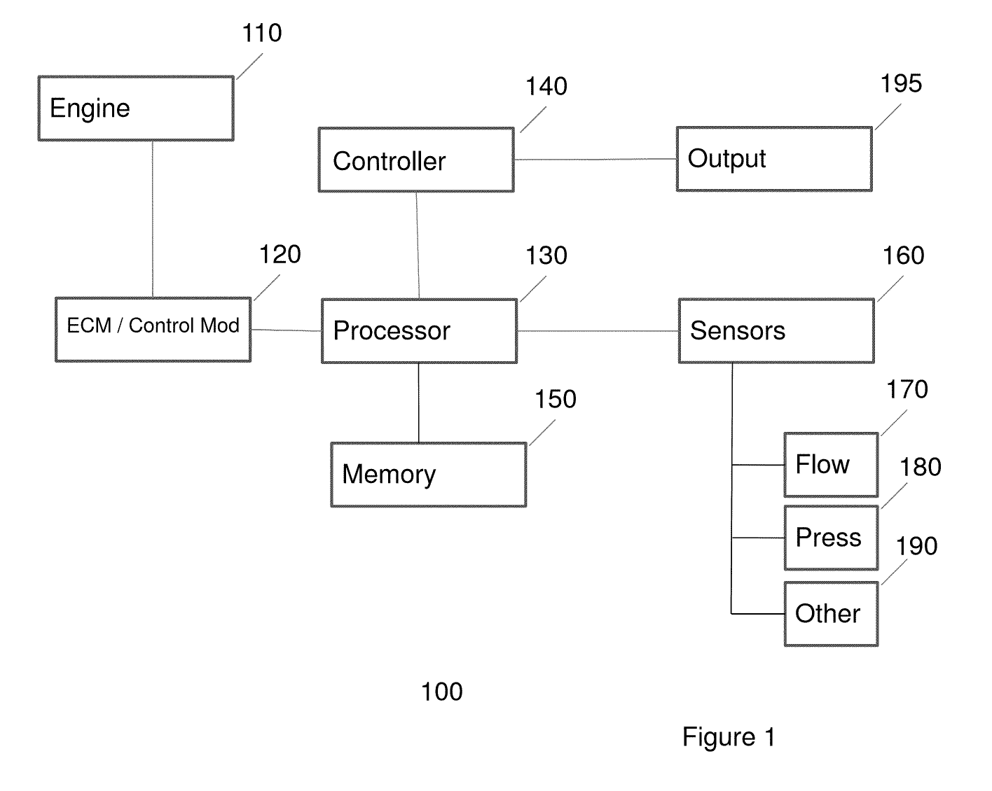

FIG. 1 is an illustration of a block diagram of one form of the control system 100 of the present invention in accordance with an embodiment of the present invention.

In FIG. 1, an internal combustion engine, battery or energy source 110 is in communication with a control module such as an engine control module (ECM) 120 which provides control information for the operation of the engine, battery or other component, such as voltage, current and power. The term ECM herein is used as an exemplar and is not intended to be limiting to the scope of the invention. The ECM 120 is in communication with a processor 130 of the control system which is in communication with a controller 140 for controlling the operation of the present invention, though other configurations are also envisioned by the present invention. System memory 150 is associated with the system processor 130 and may retain information associated with the operation and activities of the present invention. Sensor(s) for measuring and receiving information from measured sources associated with the engine operation is located at 160 and is in communication with the system processor 130 and controller 140. In one or more preferred embodiments, a hybrid engine is at 110 wherein the power, current and/or voltage of the energy source of the system is in communication with a controller at 120.

In a preferred embodiment, actuators, not pictured, may also be associated with the sensors and may be controlled by the controller for turning on/off the measurement and gathering of data inputs of the engine operation associated with the sensors. Exemplary sensors 160 may include a battery, voltage, power and current sensors (170-190) for example.

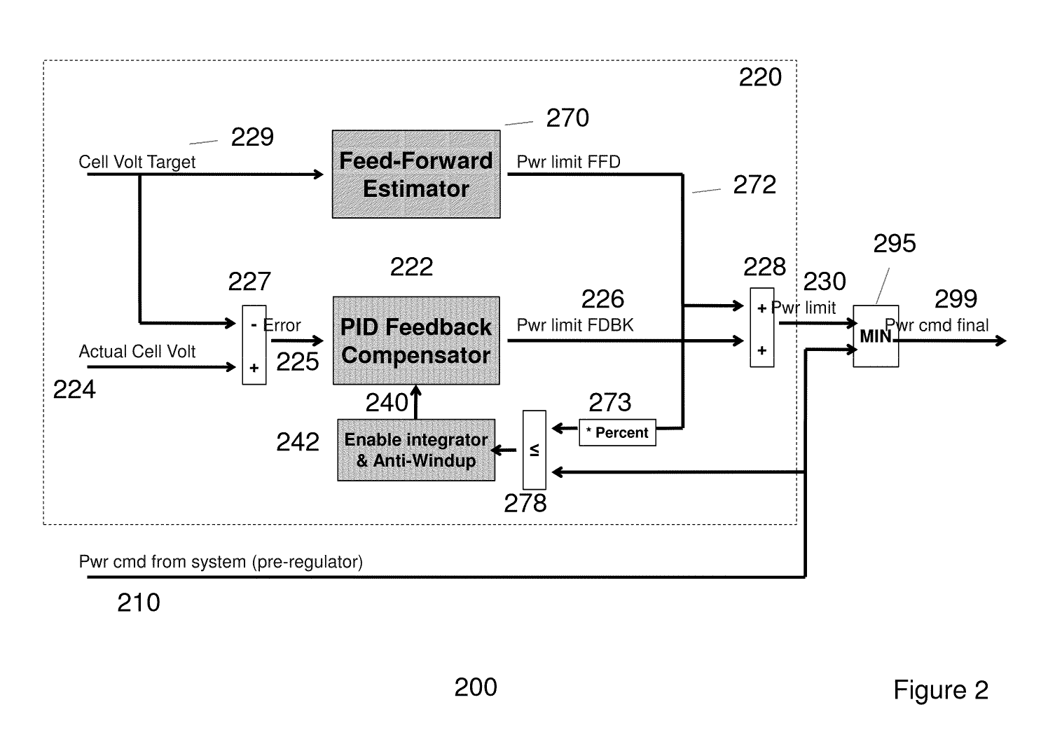

FIG. 2 is a block diagram of a method 200 of the present invention in accordance with one or more embodiments thereof. From FIG. 2, a method of the present invention may be segregated into two portions, a static portion 210 and a dynamic portion 220. The static portion 210 is the power command from the system which is independent of the battery capability. The power command 210 acts essentially as a demand element for the system, where the power command seeks to demand a power value for the system, irrespective of the battery capacity of the system. The power command 210 does not undergo amendment through the dynamic portion 220 in a single pass, but a final power command 299 is determined in relation to the power command 210 and the dynamic portion 220. As used herein, the term power command may also be used as system power demand, initial power demand, and similar.

The power command 210 can be measured or calculated using sensors, estimates, approximations or actual values, of which the value is then used as input with a comparator at 295 for determination of a final power command at 299 based on the lesser of the inputs of the power command 210 and the power limit 230 of the dynamic portion 220. Preferably, the power command is that power which the system requires independent of the available battery capability or power.

The dynamic portion 220 essentially sets forth a determination of the limitations of the capabilities of the current system having the battery, independent of the power command 210 from the system. The dynamic portion 220, in general, receives cell voltage 229 and actual cell voltage 224, and processes the inputs through a feed-forward estimator 270 and a proportional-integral-derivative (PID) feedback compensator (or controller) 222 to determine a power limit of the capability at 230. The power limit may also be referred to herein as a budget, capability limitation, estimated available battery power, available power limit, and similar.

Referring again to FIG. 2, a cell voltage target value is set forth at 229 and is used as input to the feed forward estimator (FFE) 270 to generate a power limit from the feed forward calculation (power limit FFD) at 272. The power limit FFD 272 is essentially an initial evaluation of the power available using the estimation processing of the FFE. The determination of the power limit FFD at 272 provides a first approximation of what the power limit of the system is capable of, for example. The power limit FFD 272 is also provided as input to the comparator at 228.

Also from FIG. 2, an actual cell voltage of the battery 224, determined at a predetermined period, is provided as input to a comparator at 227. A cell voltage target 229 is also provided as input to the comparator at 227. The comparator 227 determines the difference between the two inputs and defines the difference at 225 to be the cell voltage error (CVE). The CVE 225 is used as input to the PID feedback compensator 222. An adjustment of the power limit, known as the power limit feedback (power limit FDBK) 226 is output from the compensator and is used as input to the comparator at 228. Preferably, in a further embodiment, the power limit FDBK 226 is a refinement of the power limit additionally available in relation to the CVE.

At 228, the comparator is additive of the inputs resulting in an output of a power limit 230 of the dynamic portion 220. The power limit 230 reflects the initial evaluation of power available 270 and the additional amount determined from the PID compensator 222 in relation to the CVE 225. The power limit 230 is essentially a maximum power limitation of the capabilities, within 220.

The power limit 230 and the power command 210 are inputs to the comparator 295. The comparator 295 selects the lesser of the two inputs to determine a final power command (or power command final) at 299. The power command final 299 is preferably then sent as a command to a battery for a sourced power. Optimally, the present invention is situated so as to determine a final power available 230 to limit the battery power demand from the system 210 at 295 such that a final demand at 299 will not cause the battery to exceed the cell voltage threshold.

From FIG. 2, a condition may arise in one or more preferred embodiments where the step of adaptively adjusting the cell voltage is active when the cell voltage approaches the cell voltage threshold, such that the power error 225 is relatively small, such that the power limit feedback 226 is also small. The power command 210 is the power that the system requires regardless of the battery condition or output capability, for operation.

Preferably, in operation, the integrator and anti-windup processing at 242 is normally in a disabled mode until or except where a power command 210 exceeds a predetermined value. The integrator and anti-windup processing at 242 is enabled at 278 when the power command 210 is equal to or exceeds the product of the power limit FFD 270 and a predetermined threshold value 273 (i.e., percentage value) at 278. As the system power demand increases in value, independent of battery conditions, the integrator and anti-windup processing at 242 is enabled at a predetermined value 273. The predetermined value 273 is preferably defined as a predetermined percentage of the power limit FFD determination at 272 in comparison to the power command 210, such that the product of the percentage threshold multiplied by the power limit feed forward value enables the integrator and anti-windup processing to operate at a certain threshold calculation at 278 where the power command is equal to or exceeds the product calculation, and causes such to not be operative at 278 when the power command 210 is less than the product calculation at 278. In a preferred embodiment, where the power command 210 is greater than the power limit FFD multiplied by the percentage threshold, the integrator and anti-windup of 242 is enabled and the PID 222 is active to integrate up to the anti-windup limit at 240, and if the power command is not greater than the threshold calculation, then the integrator and wind-up of 242 is not enabled such that the PID is set to zero at 240.

Further from FIG. 2, by example, where the power command 210 were to have a value of 40 kW and the determined power limit 230 were to have a value of 50 kW, the power command final determination at 299 would be the lesser of the two inputs, or the 40 kW value.

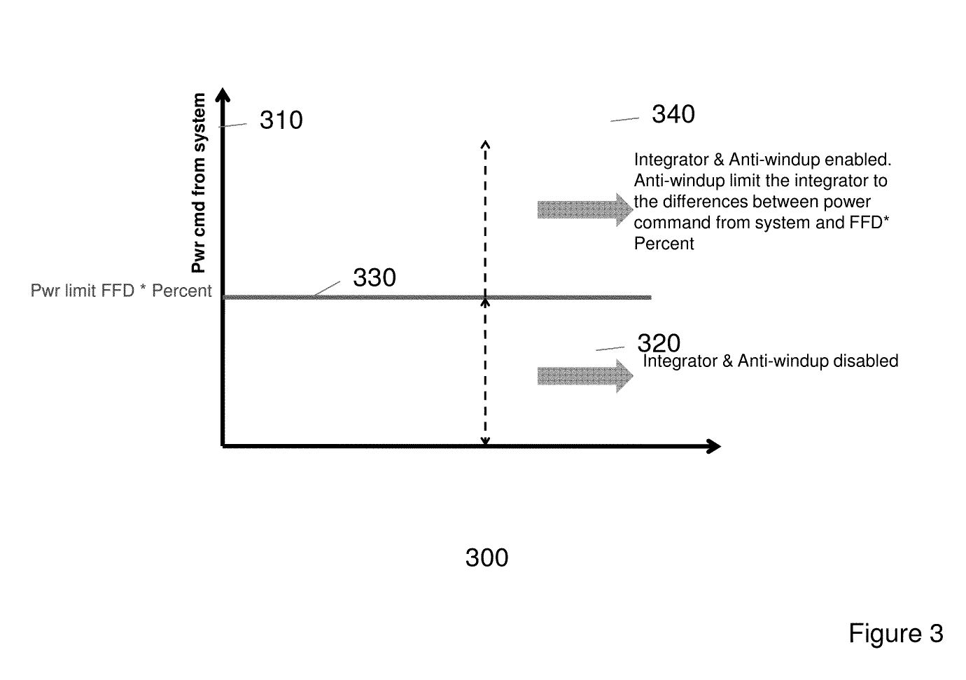

FIG. 3 sets forth a block diagram 300 hierarchy of the active or inactive operation of the integrator and anti-windup processing of the present invention in accordance with one or more preferred embodiments. From FIG. 3, as the power command from the battery system increases in value along axis 310, the integrator and anti-windup processing is disabled at 320 when at or below a predetermined value 330. The predetermined value 330 is preferably defined as a percentage of the power limit feed forward determination; such that the product of the percentage threshold multiplied by the power limit feed forward value determines the threshold 330. When the power command is equal to or greater than the product of the predetermined percentage threshold multiplied by the power limit feed forward, the integrator and anti-windup processing are operative at 340.

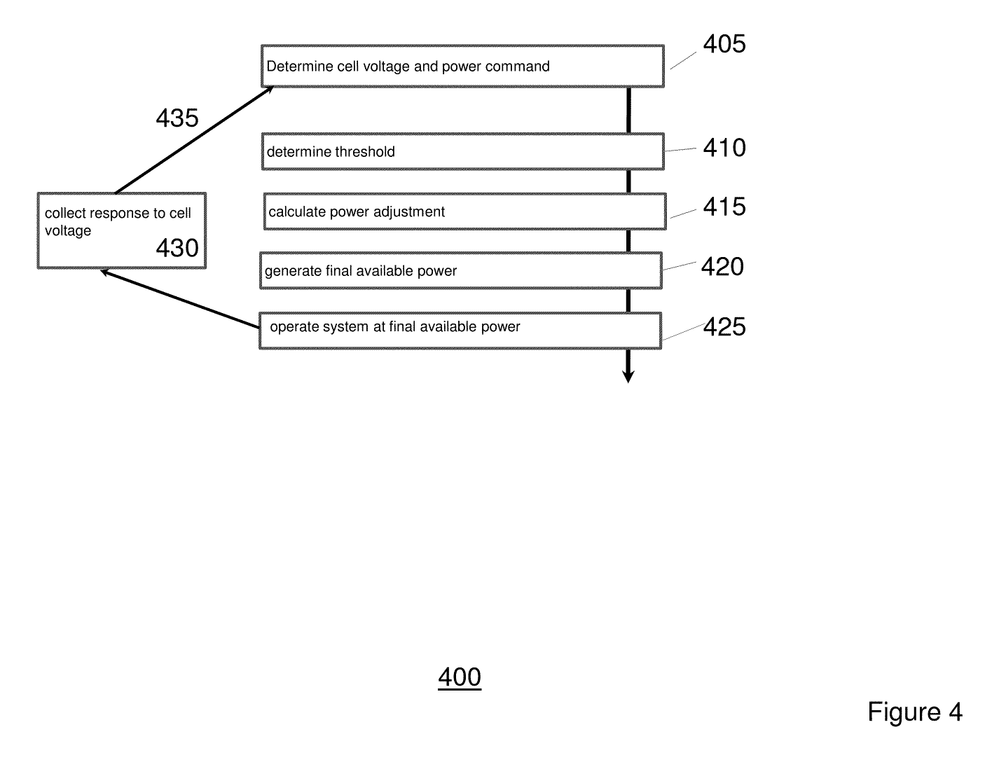

FIG. 4 sets forth a flowchart of the present invention 400 in accordance with one embodiment. From FIG. 4, a method for estimating battery available power from a battery system in relation to a cell voltage is set forth, where at 405 a cell voltage and a power command of the battery system is determined. At 410, a cell voltage threshold is determined. Calculating a power adjustment in relation to the cell voltage and the cell voltage threshold is set forth at 415. At 420, a final available power command associating the estimated battery available power with the power command and the calculated power adjustment is generated. At 425, the system is able to operate at the final available power command (also used herein as final power command or final power). Optionally, for a next cycle input, a response to the cell voltage may be collected at 430 and used as input for a following cycle at 435.

In one or more embodiments, the present invention may be used as computer software, firmware or as a simulation model, for example. In operation as a simulation model, the present invention includes a battery limit regulator which receives inputs of high cell voltage, high cell volt target, derivative gain, proportional gain, current gain, and one or more other battery power characteristics such as range of operation, voltage windows, time, etc. The high cell voltage input to the regulator may include that output of a prior operation run in which the simulation produced an actual cell voltage determination or estimation. Output of the regulator is a power limit for the battery which is then compared with the power command signal from the battery system, wherein the maximum value of the compared result is used as input power available to the battery. The battery also has operating range inputs, minimum and maximum operating ranges, where the cell volt output of the battery is determined thereafter. The cell volt output is compared with noise limits and the actual cell voltage value is determined. As a result, by using the present invention, power error can be controlled thereby reducing the error over time of the operation with a battery system through feedback, such that the voltage, power and current of the battery system are used efficiency and effectively.

In one or more embodiments, a controller of the present invention is preferably an electronic control unit comprised of a digital computer, which may include a programmable computer product of the present invention for instance, and include components connected with and in communication with one another through a back bone circuit or other bidirectional bus such as a ROM (read only memory), RAM (random access memory), CPU (microprocessor), input port, and output port, by example. The present invention may also be a circuit, application, software or other electronic means within a controller or separate and in communication with the controller as well.

In a further embodiment of the present invention, a method of monitoring and determining available power estimation for a battery in combination with one or more sensed engine characteristics is envisioned.

Advantageously, the method of the present invention eliminates the need to use look-up tables and other lagging indicators, to yield a reliable method for estimating power available for a battery system. Further, advantageously, the present invention may be used in any system, device or method that requires a battery in operation, where the present invention may act to protect the battery in the system by using the dynamic adjustment. In one or more preferred embodiments, the cell voltage is regulated at a target or within a target range.

It will be appreciated by those skilled in the art that there are many variations to the steps above that may be undertaken or altered while remaining within the scope of the present invention.

Any theory, mechanism of operation, proof, or finding stated herein is meant to further enhance understanding of the present invention and is not intended to make the present invention in any way dependent upon such theory, mechanism of operation, proof, or finding. It should be understood that while the use of the word preferable, preferably or preferred in the description above indicates that the feature so described may be more desirable, it nonetheless may not be necessary and embodiments lacking the same may be contemplated as within the scope of the invention, that scope being defined by the claims that follow.

The system described herein provides for a method for estimating battery available power from a battery system in relation to a cell voltage. By doing so, the present invention provides a system and method to reduce costs to battery damage, increases engine and associated load performances, and effectively provides for improved energy management in various operating systems.

While the invention has been described with reference to the aforementioned embodiments, it should be appreciated by those skilled in the art that the invention may be practiced otherwise than as specifically described herein without departing from the spirit and scope of the invention. It is therefore understood that the spirit and scope of the invention be limited only by the appended claims.

The system and method described above has obvious industrial applicability including that which would be useful in any environment where a user desires to reliably deploy battery systems requiring varying loads and/or hybrid engine systems, such as with, but not limited to stationary power sources and vehicle engines.

What is claimed is:

1. A method for estimating battery available power from a battery system in relation to a cell voltage, comprising:
determining the cell voltage and a power command of the battery system;
determining a cell voltage threshold;
calculating a power adjustment in relation to the cell voltage and the cell voltage threshold; and,
generating a final power command in relation to the power command and the calculated power adjustment.

2. The method of claim 1, wherein the power command is determined in relation to a specific time.

3. The method of claim 2, wherein the power command is determined instantaneously.

4. The method of claim 2, wherein the step of calculating the power adjustment includes using a regulator to determine a power limit feedback.

5. The method of claim 4, wherein the regulator is a proportional-integral-derivative (PID) regulator.

6. The method of claim 5, wherein the step of calculating the power adjustment further includes using an integrator with an anti-windup feature to provide a means for limiting the power limit feedback from the PID regulator.

7. The method of claim 4, further comprising operating at the final available power, wherein the step of generating the final available power further includes relating the power limit feedback and the power command to yield the final available power.

8. The method of claim 7, further comprising adaptively adjusting the cell voltage of the battery system in relation to a final available power command associated with the generated final available power.

9. The method of claim 8, wherein the cell voltage is regulated to operate within a predefined working boundary.

10. The method of claim 9, wherein the predefined working boundary of the cell voltage is +/−1 volt of the cell voltage.

11. The method of claim 7, further comprising a feed forward estimator for determining a forward power limit.

12. The method of claim 11, wherein the step of adaptively adjusting the cell voltage includes enabling an integrator and anti-windup processor where the power command is greater than or equal to a product of a power limit feed forward value and a predetermined enabling threshold.

13. The method of claim 11, wherein the step of adaptively adjusting the cell voltage includes disabling an integrator and anti-windup processor where the power command is less than a product of a power limit feed forward value and a predetermined enabling threshold.

14. A system for estimating battery available power from a battery system in relation to a cell voltage, comprising:
at least one sensor capable of determining cell voltage of a battery source at a specific time;
at least one data sensor operatively coupled to detect at least one or more data inputs of characteristics of a device;
a control system for the device and the battery source; and,
a data processor connected with the at least one data sensor for determining the cell voltage and a system power command of the battery source; determining a cell voltage threshold; calculating a power adjustment in relation to the cell voltage and the cell voltage threshold; and generating a final power command for the battery source.

15. The system of claim 14, wherein calculating the power adjustment includes, using a regulator to determine a power limit feedback, and the regulator is a proportional-integral-derivative (PID) regulator.

16. The system of claim 15, further comprising operating at the final available power, wherein generating the final power command further includes selecting the lesser of the sum of the power limit feedback and the power limit feed forward, and the system power command to yield the final power command.

17. The system of claim 16, further comprising adaptively adjusting the cell voltage of the battery system in relation to the final power command.

18. The system of claim 17, wherein the step of adaptively adjusting the cell voltage is operative where the system power command is greater than or equal to a product of a power limit feed forward value and a predetermined enabling threshold.

19. A computer program product stored on a computer usable medium for estimating battery available power from a battery system in relation to a cell voltage, comprising, a computer readable program for causing a computer to control an execution of an application within a memory control device in operable communications with a device; the computer readable program when executed by a computer for:
determining the cell voltage and a power command of the battery system;
determining a cell voltage threshold;
calculating a power adjustment in relation to the cell voltage and the cell voltage threshold for adaptively regulating the cell voltage; and,
generating a final power command in relation to the estimated battery available power, the power command and the calculated power adjustment.

20. The product of claim 19, wherein the product is for one or more of an internal combustion engine having a battery-based power source or supplemental power source, a hybrid engine, a battery-powered power source, and a battery-based engine having one or more supplemental power sources.

21. The product of claim 20, further comprising operating at the final power command, wherein the step of generating the final power command further includes selecting the lesser of a sum of the power limit feedback and a power limit feed forward and the power command to yield the final power command.
